(19) United States
(12) Patent Application Publication
(10) Pub. No.: US 2012/0200992 A1
(43) Pub. Date: Aug. 9, 2012

(54) SYSTEM AND METHOD FOR CONCURRENT MANUFACTURING, TESTING, AND INTEGRATION OF A MODULAR DATA CENTER

(75) Inventors: Ty Schmitt, Round Rock, TX (US); Mark M. Bailey, Burnet, TX (US); Anthony Middleton, Round Rock, TX (US); Tyler Duncan, Austin, TX (US)

(73) Assignee: DELL PRODUCTS, LP.

(21) Appl. No.: 13/021,971

(22) Filed: Feb. 7, 2011

(51) Int. Cl. H05K 7/00; B23P 17/00; B23P 11/00; H05K 13/04

(52) U.S. Cl. 361/679.02; 29/592; 29/407.01; 29/428

(57) ABSTRACT

In accordance with the present disclosure, a system and method for concurrent manufacturing, testing, and integration of a modular data center is presented. According to the disclosure, a first component of a modular data center and a second component of a modular data center may be separately and concurrently manufactured. The first component may include a first pre-designed integration element, and the second component may include a second pre-designed integration element. The manufactured first component and the manufactured second component are then integrated, using an integration process which utilizes the first pre-designed integration element and the second pre-designed integration element.

### CROSS REFERENCES TO RELATED APPLICATIONS

This application is related to co-pending U.S. patent application Ser. No. ______ [Attorney Docket No. 061295.4239, DC-18496] entitled “System and Method for Designing a Configurable Modular Data Center” which was filed on ______, 2011, U.S. patent application Ser. No. ______ [Attorney Docket No. 016295.4241, DC-18500] entitled “System and Method for a Modular Fluid Handling System with Modes in a Modular Data Center” which was also filed on ______, 2011, U.S. patent application Ser. No. ______ [Attorney Docket No. 016295.4242, DC-18502] entitled “System and Method for Structural, Modular Power Distribution in a Modular Data Center”, which was also filed on ______, 2011, U.S. patent application Ser. No. ______ [Attorney Docket No. 016295.4243, DC-18503] entitled “System and Method for an Optimizable Rack Solution”, which was also filed on ______, 2011, all of which are incorporated herein by reference for all purposes.

### TECHNICAL FIELD

The present disclosure relates generally to the operation of computer systems and information handling systems, and, more particularly, to a system and method for concurrent manufacturing, testing, and integration of a modular data center.

### BACKGROUND

As the value and use of information continues to increase, individuals and businesses seek additional ways to process and store information. One option available to these users is an information handling system. An information handling system generally processes, compiles, stores, and/or communicates information or data for business, personal, or other purposes thereby allowing users to take advantage of the value of the information. Because technology and information handling needs and requirements vary between different users or applications, information handling systems may vary with respect to the type of information handled; the methods for handling the information; the methods for processing, storing or communicating the information; the amount of information processed, stored, or communicated; and the speed and efficiency with which the information is processed, stored, or communicated. The variations in information handling systems allow for information handling systems to be general or configured for a specific user or specific use such as financial transaction processing, airline reservations, enterprise data storage, or global communications. In addition, information handling systems may include or comprise a variety of hardware and software components that may be configured to process, store, and communicate information and may include one or more computer systems, data storage systems, and networking systems.

A data center typically includes a plurality of information handling systems arranged in racks. In a modular data center, such as a containerized data center, the racks and information handling systems are included in a modular enclosure, such as a shipping container. Manufacturing a containerized data center is difficult because of the limited space provided by the shipping container enclosure. Some components of a modular data center are either wholly or partially manufactured within the modular enclosure due to current manufacturing and integration limitations; namely, current containerized data centers typically require customized configuration. This is problematic, because many components must be tested before the modular data center can be shipped, and waiting until after the modular enclosure is completed to built and test the components increases the overall manufacturing and deployment time. One example is the IT equipment, comprised of a rack populated with information handling systems. Current manufacturing techniques include building the racks directly into the modular enclosure or building the racks separately and then installing them into the completed enclosure. In either case, the racks are not populated until after they are integrated within the modular enclosure, meaning the IT equipment is not completed and tested until after the modular enclosure is manufactured.

### SUMMARY

In accordance with the present disclosure, a system and method for concurrent manufacturing, testing, and integration of a modular data center is presented. According to the disclosure, a first component of a modular data center and a second component of a modular data center may be separately and concurrently manufactured. The first component may include a first integration element, and the second component may include a second integration element. The manufactured first component and the manufactured second component are then integrated, using an integration process which utilizes the first integration element and the second integration element.

The system and method disclosed herein is technically advantageous because it reduces the time it takes to manufacture and deploy a modular data center. Instead of waiting until one component is manufactured before manufacturing and testing a second component, the system and method presented herein allows for the concurrent manufacture of multiple components of a modular data center, which can then be integrated quickly and efficiently using an integration process as described herein.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 is one embodiment of a component of a modular data center.

FIG. 2 is one embodiment of an integration process according to one aspect of the present invention.

FIG. 3 is another embodiment of an integration process according to one aspect of the present invention.

FIG. 4 is a flow diagram for one embodiment of a method of manufacturing a modular data center incorporating an integration process, according to one aspect of the present invention.

FIG. 5 is a flow diagram for another embodiment of a method of manufacturing a modular data center incorporating an integration process, according to one aspect of the present invention.

### DETAILED DESCRIPTION

For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communication with external devices as well as various input and output (I/O) devices, such as a keyboard, a mouse, and a video display. The information handling system may also include one or more buses operable to transmit communications between the various hardware components.

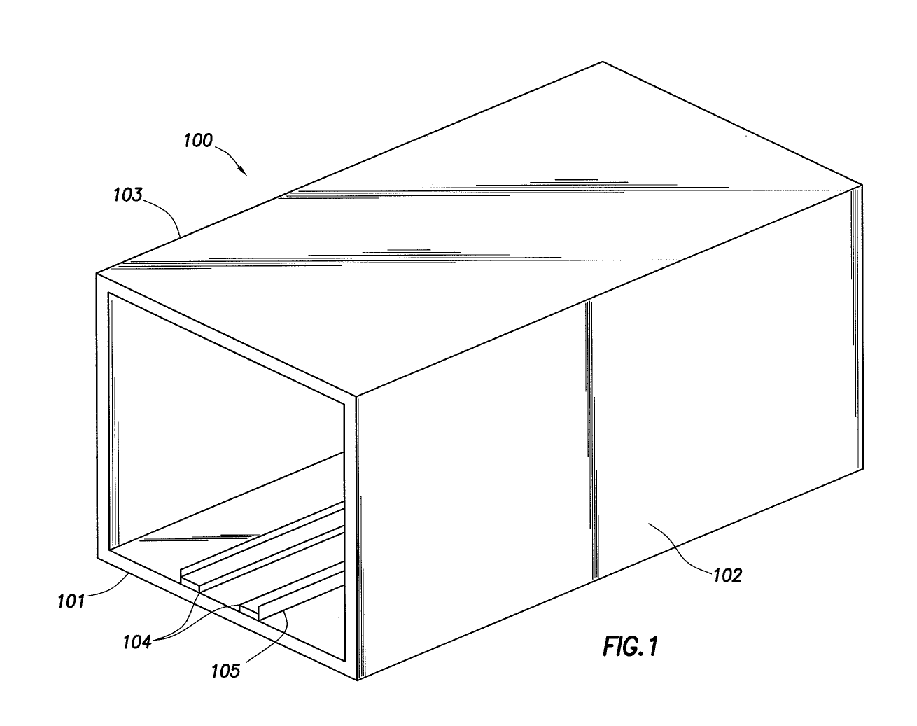

FIG. 1 shows one embodiment of a component of a modular data center, container 100, according to aspects of the present invention. The container 100 of FIG. 1 may be, for example, a standard ISO shipping container as is typically used in a containerized data center. The container 100 may include a base 101, two side walls 102, and top 103. The container 100 may include an integration element, such as tracks 104 with side walls 105, or structures that are meant, at least in part, to be used in an integration process designed to integrate the structural enclosure 100 with a second component. In some embodiments, the component itself may be designed to facilitate integration with other manufactured components, and in other embodiments, like in FIG. 1, the component may include separate integration elements, like tracks 104 with side walls 105, which may be manufactured as part of a first component and may be sized according to dimensions of the second component which is to be integrated with the first component. For example, the tracks 104 with side walls 105 may be sized according to dimensions of a plurality of racks fully populated with information handling systems. Tracks 104 may extend the entire length of the container 100, so that a plurality of racks may be integrated with the structural enclosure 100 in a single row down the middle of the structural enclosure. Additionally, the width between the side walls 105 of the tracks 104 may be designed according to the depth of each of the plurality of racks that are to be integrated into the structural enclosure.

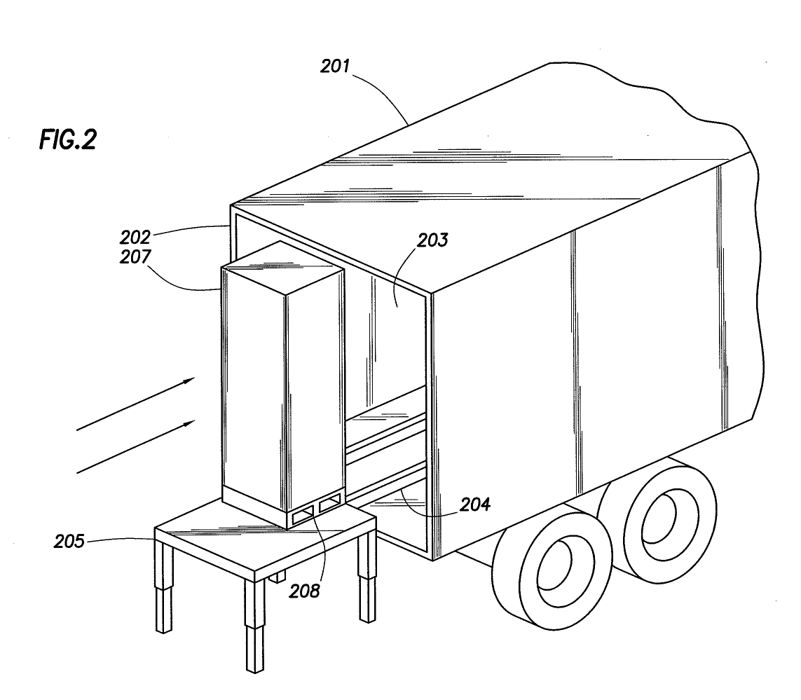

FIG. 2 is an illustration of an integration process designed to integrate a component similar to the container FIG. 1 with a second component. In the present embodiment, the second component is a plurality of fully populated information handling systems. As can be seen, FIG. 2 includes a container 201. Unlike the container in FIG. 1, container 201 is shown deployed on wheels, such that it can easily be connected as the load of a hauling mechanism, including a tractor trailer. This may facilitate some aspects of an integration process that will be discussed below in detail. Container 201 includes an outer structure 202, which defines an interior 203. The interior 203 of the container may include rails 204 similar to the rails in container 100, positioned on the bottom of the container 201.

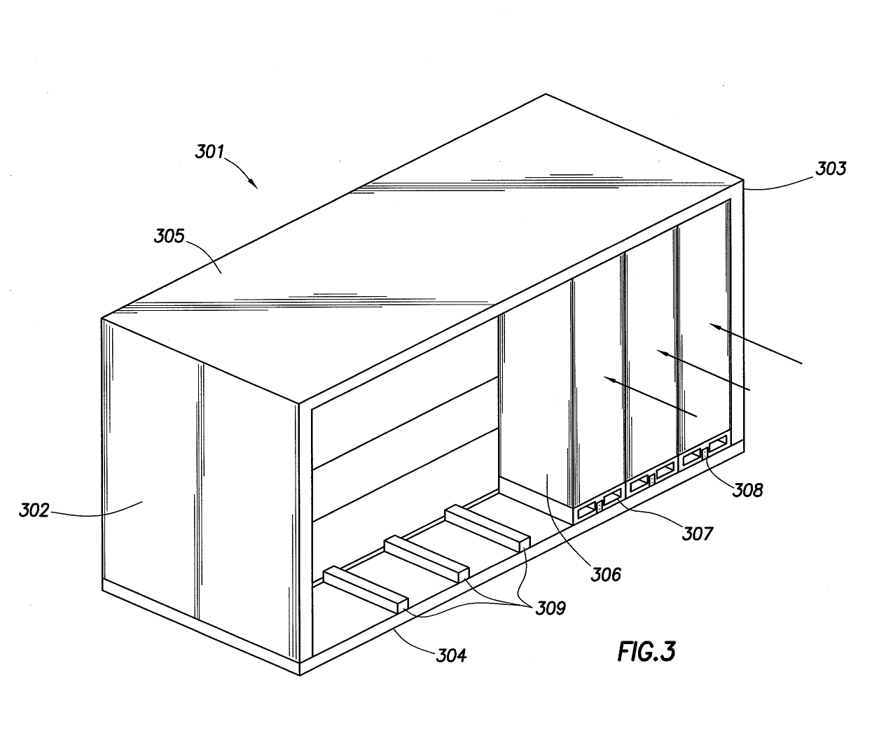

On the end of container 201 is integration platform 205. The integration platform 205 may include a platform that is generally aligned with the top of the track 204 in the interior of the container 201, the integration platform being supported by multiple legs. The integration platform 205 is one example of integration equipment for use in an integration process. In the embodiment of the integration process shown in FIG. 3, the integration platform 205 serves as a staging area, where a component to be integrated into the container 201 can be set and aligned with tracks 204. The integration platform 205 may take a variety of configurations, and may include additional features, such as side rails and adjustable legs to raise and lower the height of the platform, and still function to provide a staging area in the illustrated integration process of FIG. 2.

Resting on the integration platform 205 is one example of a second component of a modular data center according to aspects of the present invention, rack component 207, which includes a rack that is populated with information handling systems. Rack component 207 is preferably fully tested before being placed in the staging area and integrated into the container 201. The rack component 207 includes another example of an integration element, fork lift slots 208. Fork lift slots 208 may be manufactured into the structural base of the rack component 207. Manufacturing integration elements, such as fork lift slots 208 into the rack component 207, is preferable, because the rack component 207 can then be populated with information handling systems, tested, and integrated without any further steps which might delay deployment of the modular data center. A preferred embodiment of a rack component is a space optimizable rack, which is described in the cross-referenced application entitled “System and Method for an Optimizable Rack Solution.”

In practice, integrating rack components, including rack component 207, into container 201 requires positioning the integration platform 205 at the end of container 201 and at a level which generally aligns with the top of tracks 204. Next, rack component 207 may be lifted onto the integration platform 205 using a common fork lift, or any other suitable lifting mechanism. Once on the platform 205, the rack component 207 can be moved into the container 201. Moving the fully populated rack 207 into the container 201 may include sliding the fully populated rack 207 onto track 204. The fully populated rack 207 may then be moved along track 207, away from platform 205. Side walls, such as those shown in FIG. 1, may keep the rack component from sliding off of the tracks and may also keep rack component from shifting once installed. Once the rack component 207 is moved away from the platform 205, another rack component can be lifted onto the integration platform to be moved and integrated into the container 201. This process can be repeated until each of the rack components needed for the modular data center have been incorporated into the container 201.

As discussed above, each integration element—the fork lift slots 208 of the rack component 207 and the tracks 204 of the container 201—may both be utilized in and designed partially for the integration process shown in FIG. 2. For example, each of the rack components 207 may include fork lift slots 208 because the integration process requires that the rack components 207 be lifted to be integrated. Likewise, as previously mention, the tracks 204 can be sized according to the dimensions of the rack components 207, or any other component, such as power or cooling equipment that may be integrated with container 201.

FIG. 3 illustrates another embodiment of an integration process for two components of a modular data center, according to one embodiment of the invention. FIG. 3 includes a structure 301. Structure 301 includes a front 302, a back 303, a base 304, and a top 305. The structure 301 may preferably be an IT module from a modular data center as described in related application entitled “System and Method for Designing a Configurable Modular Data Center.” As can be seen, the structure 301 does not include side walls. The structure 301 may be designed without sidewalls, or may include removable sidewalls, which can be removed as part of the integration process shown in FIG. 3. The open sides of structure 301 is another example of an integration element, and may have been included specifically for the purposes of integrating other components with the structure 301, or may have other uses, such as allowing airflow through the structure 301, as is described in the cross-referenced application entitled “System and Method for Fluid Handling Systems with Modes in a Modular Data Center.”

The integration process illustrated in FIG. 3 is directed to integrating rack components 306 into structure 305. The rack components 306 are preferably fully populated with information handling systems and tested before being integrated into the structure 301. Each of the rack components include fork lift slots 307. Each of the rack components 206 may also include grooves 308 running parallel to the fork lift slots 307. The grooves 308 may align with tracks 309, proximate the base of structure 301. Integrating the structure 301 with the rack components 306 may include lifting each of the rack components with a fork lift and inserting the rack components into the structure 301. In some embodiment, the structure may be mounted on wheels in a manner similar to structure in FIG. 2. Once the rack component is lifted, the grooves 308 may be aligned with tracks 309 and the rack component may be inserted such that the track engages the groove and the rack component is locked into place. In some embodiments, such as the embodiments shown in FIG. 3, the rack component may include a plate by which the rack component is bolted to the track. Each of the tracks 309, the grooves 308, and the plate may be seen as examples of integration elements for use in the integration process described in this disclosure

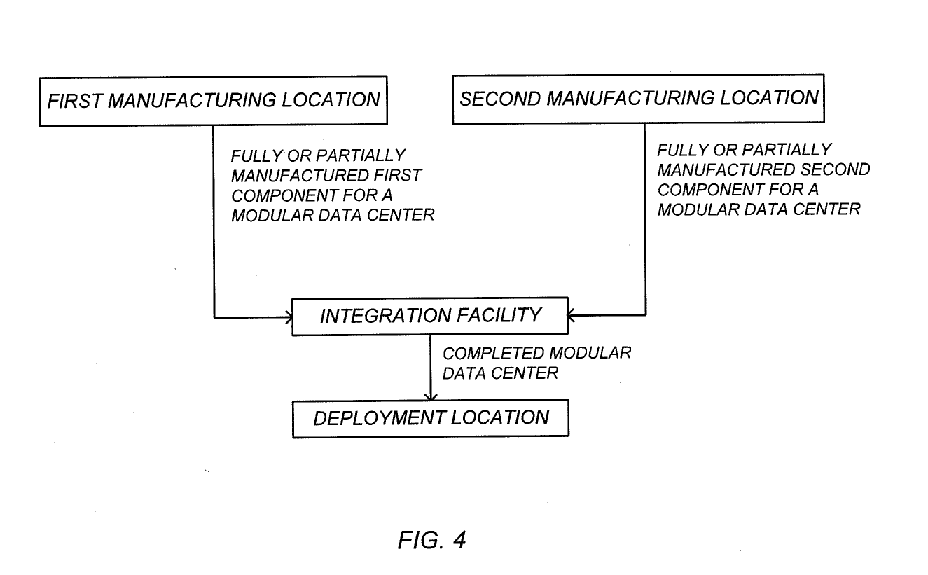

FIG. 4 is block illustration of a preferred manufacturing system according to one aspect of the present invention. The manufacturing system illustrated in FIG. 4 includes a First Manufacturing Location. The First Manufacturing Location may be dedicated to manufacturing and testing one particular component of a modular data center or a subset of components of a modular data center. For example, the First Manufacturing Location may include the necessary equipment to manufacture, wire, and test a container of a modular data center, such as those illustrated in FIGS. 2 and 3. The First Manufacturing Location may either fully manufacture or partially manufacture the container. In some embodiments, some additional assembly or testing may be completed at a different location, such as the Integration Facility. In other embodiments, a container may be fully manufactured and mounted on wheels, as illustrated in FIG. 2. The manufactured container can then be transported as whole to the Integration Facility, where it can be integrated with other components of the modular data center.

The manufacturing system illustrated in FIG. 2 may also include a Second Manufacturing Location. Like the First Manufacturing Location, the Second Manufacturing Location may be dedicated to manufacturing and testing one particular component of a modular data center or a subset of components of an entire modular data center. For example, the Second Manufacturing Location may include the necessary equipment to manufacture and populated racks components with information handling systems and test the rack components once populated. In another embodiment, the Second Manufacturing Location may receive the manufactured rack assembly and a plurality of information handling systems from additional locations, and manufacture the rack components by populating the rack assemblies with information handling systems and testing the rack components once populated. In yet another embodiment, the Second Manufacturing Location may only partially manufacture a component before shipping the component to the Integration Facility, which may be designed to complete the manufacturing of the component, such as testing a rack component after it is populated with information handling systems at the Second Manufacturing Location.

The Integration Facility shown in FIG. 4 receives the components of a modular data center from the other manufacturing locations and integrates the components to complete the modular data center. In other embodiments, some of the components of the modular data center, including the rack components and container, may be manufactured at the integration facility. In yet other embodiment, the Integration Facility may receive a plurality of components from a plurality of different manufacturing locations, and store some or all of the components until the components necessary for integration are received. For example, the rack components for a modular data center may be manufactured and tested faster than a container for the modular data center can be manufactured. The manufactured and tested rack components may be shipped to the Integration Facility and stored until the manufactured container arrives at the Integration Facility.

The Integration Facility shown in FIG. 4 may include integration equipment designed to carry out a plurality of integration processes at the Integration Facility. This integration equipment may include the integration platform and fork lifts described above with regard to the integration process of FIG. 2. The Integration Facility may be the designated place to assemble and integrate each of the components of the modular data center, so that the end product produced at the Integration Facility is the completed modular data center. As can be seen in FIG. 4, once completed, the modular data center may be shipped directly from the Integration Facility to the deployment location for use.

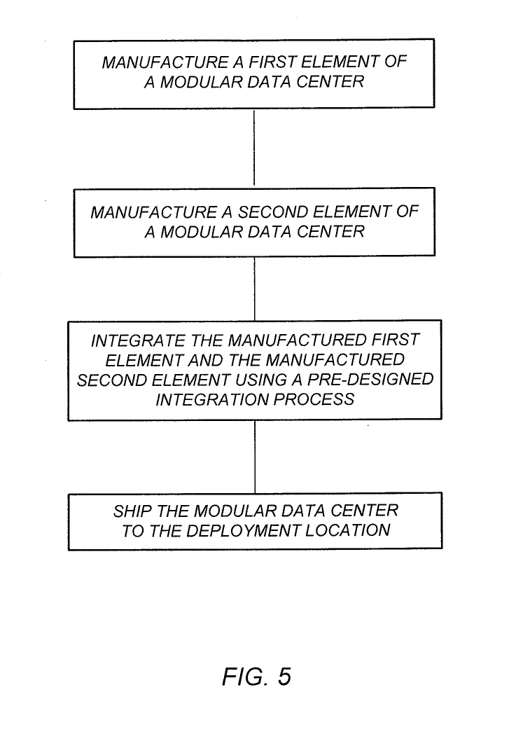

Shown in FIG. 5 is a flow diagram of a manufacturing method according to one embodiment of the invention. One step of the method includes manufacturing a first component of the modular data center. Manufacturing a first component may include a variety of actions, including building the element, assembling the element from components, testing the element once completed, or any other manufacturing action well known in the art. The first component may be one of a variety of components including an enclosure, fluid handling equipment, such as fans, power elements, such as breaker boxes, or any other component of a modular data center well known in the art. In a preferred embodiment, the first component comprises the structural enclosure which holds the IT equipment, such as the racks and information handling systems of the modular data center. As shown above in FIGS. 2 and 3, the structural enclosure may be an ISO shipping container or a modular element, such as an IT module, and may include an integration element for use in a pre-designed integration process.

The method further includes the step of concurrently and separately manufacturing a second component of the modular data center. Manufacturing a second component may include a variety of actions, including building the element, assembling the element from components, testing the element once completed, or any other manufacturing action well known in the art. Concurrently and separately manufacturing the second component may include manufacturing at a separate location or at the same location, provided the second component is manufactured separate from the first element. The second component may include a variety of components including a enclosures, fluid handling elements, such as fans, power elements, such as breaker boxes, or any other component of a modular data center well known in the art. In a preferred embodiment, the second component may include all or some of the IT equipment for the data center, such as rack components, as described above with regards to FIGS. 2 and 3. Manufacturing the rack components may include fully populating the racks for the data center with information handling systems, and testing the computing functionality of each rack of information handling systems. As shown above in FIGS. 2 and 3, the rack component may include an integration element, such as fork lift holes, which may be used in a pre-designed integration process.

The method of FIG. 5 also include the step of integrating the manufactured first element and the manufactured second element using a pre-designed integration process. The integration process may be designed to combine a plurality of components of a modular data center, such as the fluid handling components, power components, etc. In a preferred embodiment, one pre-designed integration process includes the integration process shown in FIG. 2. Like the integration process of FIG. 2, other pre-designed integration processes may include the use of integration equipment, dedicated and designed for the integration process, such as the integration platform of FIG. 2. Additionally, the integration process will preferably utilize integration elements from each of the corresponding components to integrate the components of the modular data center. For example, the integration process of FIG. 2 utilizes the tracks 204 of container 201 and the fork lift slots 208 of the rack component 207 to integrate the rack component with the container. Finally, after the integration is complete, the modular data center may be shipped to a deployment location, where it will be used as a data center.

Although the present disclosure has been described in detail, it should be understood that various changes, substitutions, and alterations can be made hereto without departing from the spirit and the scope of the invention as defined by the appended claims.

What is claimed is:

1. A method for manufacturing a modular data center, comprising:
manufacturing a first component of the modular data center, wherein the first component includes a first integration element;
separately manufacturing a second component of the modular data center, wherein the second component includes a second integration element;
integrating the manufactured second element and the manufactured first element using an pre-designed integration process that utilizes the first and second integration elements.

2. The method for manufacturing a modular data center of claim 1, wherein the first element is a container of the modular data center

3. The method for manufacturing a modular data center of claim 2, wherein the second component is a plurality of rack components;

4. The method for manufacturing a modular data center of claim 3, wherein manufacturing the plurality of IT equipment includes populating racks with the information handling systems and testing the populated racks.

5. The method for manufacturing a modular data center of claim 3, wherein the first integration element comprises at least one track disposed within the container.

6. The method for manufacturing a modular data center of claim 5, wherein the second integration element includes fork lift slots disposed in each of the plurality of rack components.

7. The method for manufacturing a modular data center of claim 6, wherein the second integration element further includes a groove disposed in a base of each of the plurality of rack components.

8. The method for manufacturing a modular data center of claim 2, wherein the first component and the second component are manufactured concurrently.

9. A method for manufacturing a modular data center, comprising:
receiving a manufactured first component of a modular data center, wherein the manufactured first component includes a first integration element;
receiving a manufactured second component of a modular data center, wherein the manufactured second component includes a second integration element;
integrating the manufactured first component and the manufactured second component using a pre-designed integration process that utilizes the first integration element and the second integration element.

10. The method for manufacturing a modular data center of claim 9, wherein the manufactured first element is a container of the modular data center.

11. The method for manufacturing a modular data center of claim 10, wherein the manufactured second component is a plurality of rack components that are populated with information handling systems and tested to insure functionality.

12. The method for manufacturing a modular data center of claim 10, wherein the first integration element comprises a track disposed within the container.

13. The method for manufacturing a modular data center of claim 11, wherein the second integration element includes fork lift slots disposed in each of the plurality of rack components.

14. The method for manufacturing a modular data center of claim 9, wherein the integration process is completed using pre-designed integration equipment located at an integration facility.

15. The method for manufacturing a modular data center of claim 14, wherein the first element and/or second element are wholly or partially manufactured at the integration facility.

16. The method for manufacturing a modular data center of claim 14, wherein the pre-designed integration equipment includes an integration platform.

17. A modular data center, comprising:
a container, wherein the container includes a first integration element,
a plurality of rack components integrated into the container, wherein each of the plurality of rack components includes a second integration element; and
wherein the plurality of rack components are populated with information handling systems and tested before being integrated with the container in an integration process that utilizes both the first integration element and the second integration element.

18. The modular data center of claim 17, wherein the first integration element is a track.

19. The modular data center of claim 18, wherein the second integration element is fork lift slots.

20. The modular data center of claim 19, wherein the integration process is completed at an integration facility what includes integration equipment which utilizes the first integration element and second integration element.
